(19) United States
(12) Patent Application Publication
(10) Pub. No.: US 2024/0026533 A1
(43) Pub. Date: Jan. 25, 2024

(54) Direct Coating of a Membrane with a Catalyst

(71) Applicant: Siemens Aktiengesellschaft, München (DE)

(72) Inventors: Jens Dahl Jensen, Berlin (DE); Ursus Krüger, Berlin (DE); Gabriele Winkler, Berlin (DE)

(73) Assignee: Siemens Aktiengesellschaft, München (DE)

(21) Appl. No.: 18/043,162

(22) PCT Filed: Jul. 7, 2021
(86) PCT No.: PCT/EP2021/068876

§ 371 Date: Feb. 27, 2023

(30) Foreign Application Priority Data
Sep. 2, 2020 (EP) 20194097.0

(51) Int. Cl. C23C 16/455; C23C 16/06

(52) U.S. Cl. CPC C23C 16/4554; C23C 16/06; C23C 16/45544

(57) ABSTRACT

Various embodiments of the teachings herein include a method for coating a membrane with a catalyst. An example method includes: positioning a membrane in a reactor chamber; coating the membrane on a first surface with a metal by atomic layer deposition; purging the reactor chamber to remove any metal remaining in the reactor chamber and not deposited on the at least one surface of the membrane; generating a plasma using a plasma source within the reactor chamber and contacting the plasma with the metal deposited on the first surface of the membrane; and purging the reactor chamber to remove volatile compounds generated during the reaction. A grid or a perforated plate separates the plasma source and the coated membrane.

### CROSS-REFERENCE TO RELATED APPLICATIONS

This application is a U.S. National Stage Application of International Application No. PCT/EP2021/068876 filed Jul. 7, 2021, which designates the United States of America, and claims priority to EP Application No. 20194097.0 filed Sep. 2, 2020, the contents of which are hereby incorporated by reference in their entirety.

### TECHNICAL FIELD

The present disclosure relates to membranes. Various embodiments include methods for coating a membrane with a catalyst, membranes produced thereby, electrolysis cells comprising such a membrane, and/or devices for executing the methods.

### BACKGROUND

The conversion and storage of energy from renewable sources such as wind, water, and sun over relatively long periods of time takes place inter alia in what are known power-to-gas plants. In these plants, the green electricity generated from wind, sun or hydropower is converted into hydrogen by electrochemical decomposition (electrolysis) of water. Hydrogen is an energy carrier that, unlike fossil fuels, does not give rise to harmful emissions of carbon dioxide when burned. Moreover, the hydrogen can easily be fed into the existing natural gas infrastructure.

The hydrogen in the power-to-gas plant is generated inter alia via dry polymer electrolyte membrane electrolysis (PEM electrolysis). PEM electrolysis consists of a hydrogen evolution reaction (HER) at the cathode and an oxygen evolution reaction (OER) at the anode. To obtain pure hydrogen at the cathode, the HER and OER reactions are spatially separated by a membrane, usually a proton-exchange membrane, typically made of Nafion. Its special chemical structure makes this membrane permeable to protons (H atoms) and impermeable to gases and electrolytes.

Since the HER and OER reactions are kinetically very sluggish, these reactions require efficient electrocatalysts. The catalysts reduce the energy required for water splitting and increase the splitting rate. The most effective electrocatalysts are the platinum group metals (Ru, Rh, Pd, Os, Ir, Pt) and oxides thereof.

At present, either commercially available iridium catalysts, for example IrO₂/TiO₂ from Umicore (IrO₂ supported on TiO₂), Ir black from Alfa Aesar, or simply IrO₂ from Alfa Aesar and Sigma Aldrich, or antimony tin oxide (ATO) particles coated with IrO₂ by reduction of an inorganic precursor such as iridium(III) chloride with the reducing agent sodium borohydride (NaBH₄) in anhydrous ethanol with addition of inert gas, or dihydrogen hexachloroiridate(IV) hydrate (H₂IrCl₆·H₂O) coated with the reducing agent ethylene glycol, at a pH of 11 in distilled water under protective gas and with sonication and heating. The catalyst particles are usually processed into an ink with 2-propanol, distilled water, and an approx. 15 to 20% Nafion ionomer solution as a binder and for charge transport to the current collectors. The ink is then applied to the polymer membrane either directly by spraying or squeegeeing, or indirectly by means of the decal method via a transfer film.

The elements of the platinum group occur in very low abundance in the earth's crust and are accordingly costly when seeking to scale up energy conversion processes. It would therefore be advantageous if the electrocatalysts were applied directly to the membrane in a very thin layer, for example a few nanometers thick, by means of a special coating method. The aim of the special coating method would be to minimize the amount of platinum group elements used and to improve the catalytic reactivity thereof.

### SUMMARY

Reducing the amount of catalyst on a membrane, where the catalyst may be a metal compound, can be achieved by coating the membrane, for example a proton-exchange or polymer exchange membrane, directly by vapor deposition of the catalyst via a precursor and subsequent layer formation using a plasma. The reduction in the amount of catalyst is achieved here not by increasing the active area, but by the nature of the deposition process. This technology permits savings of up to 99.3% by weight of the amount of catalyst compared to conventional application methods using ink-spraying technology or a decal process with the same active area.

For example, some embodiments include a method for coating a membrane (6; 22) with a catalyst (7, 8), comprising: a) providing (1) a membrane (6; 22) in a reactor chamber; b) coating (2) the membrane (6; 22) on at least a first surface with at least one metal and/or at least one metal compound by atomic layer deposition, wherein the at least one metal and/or at least one metal compound is fed into the reactor chamber and coated onto the at least one surface of the membrane (6; 22) by atomic layer deposition; c) purging (3) the reactor chamber in such a way that metal remaining in the reactor chamber and not deposited on the at least one surface of the membrane (6; 22) and/or metal compound remaining in the reactor chamber and not deposited on the at least one surface of the membrane (6; 22) is removed from the reactor chamber; d) generating (4) a plasma (33) by means of a plasma source (27) within the reactor chamber and contacting the plasma (33) with the at least one metal deposited on the at least one surface of the membrane (6; 22) and/or at least one metal compound deposited on the at least one surface of the membrane (6; 22), wherein the plasma (33) reacts with the at least one metal and/or at least one metal compound; and e) purging (5) the reactor chamber in such a way that volatile compounds generated during the reaction in step d) are removed, wherein a grid (34) or a perforated plate is in step d) arranged between the plasma source (27) and the coated membrane.

In some embodiments, the membrane 6; 22) is a polymer exchange membrane.

In some embodiments, the at least one metal or at least one metal compound comprises a metal selected from the group consisting of Ru, Rh, Pd, Ag, Os, Ir, Pt, Au.

In some embodiments, the plasma is in step d) generated with a gas comprising oxygen, the reaction giving rise to an oxygen compound of the at least one metal and/or of the at least one metal compound.

In some embodiments, step b) takes place at a temperature of less than 300° C., e.g. of less than 100° C.

In some embodiments, in step b) of coating, the at least one metal and/or at least one metal compound and/or a precursor of the at least one metal is conveyed into the reactor chamber by means of an inert carrier gas.

In some embodiments, the plasma in step d) is generated by means of a hollow-cathode plasma source (31).

In some embodiments, a DC voltage generator (35) is connected to a substrate holder on which the membrane is fixed, and to the grid (34) or perforated plate, the grid (34) or perforated plate being connected to a negative pole of the DC voltage generator (35).

In some embodiments, during step d), a superimposed pulsed voltage is applied to the DC voltage generator (35) over a basic voltage in such a way that a positive and a negative voltage is alternately applied to the grid (34) or perforated plate.

In some embodiments, the superimposed voltage has a pulse frequency of 0.5 to 30 kHz, e.g. 1 to 25 kHz.

In some embodiments, steps b) to e) are carried out multiple times in succession.

As another example, some embodiments include a coated membrane produced by one or more of the methods described herein.

As another example, some embodiments include an electrolysis cell comprising a coated membrane as described herein.

As another example, some embodiments include use of a coated membrane as described herein in an electrolysis cell, e.g. in a PEM electrolysis in which the membrane is a polymer electrolyte membrane (PEM).

As another example, some embodiments include a device for coating a membrane (6; 22), comprising: a reactor (20) comprising a reactor chamber; a substrate holder (21) in the reactor chamber that is designed to hold a membrane (6; 22); a plasma source (27) that is arranged inside the reactor chamber and is designed to generate from a reaction gas a plasma (33) at least partially inside the reactor chamber; a first supply device for at least one metal and/or at least one metal compound that is designed to supply at least one metal and/or at least one metal compound to the reactor chamber; a second supply device for the reaction gas, which is designed to supply the reaction gas to the reactor chamber in such a way that a plasma (33) can be generated from the reaction gas with the plasma source (27); and at least one third supply device for a purge gas, which is designed to supply at least one purge gas to the reactor chamber, it being possible to combine the at least one third supply device at least in part with the first and/or second supply device, further comprising: a grid (34) or perforated plate arranged between the plasma source (27) and the substrate holder (21).

### BRIEF DESCRIPTION OF THE DRAWINGS

The appended drawings illustrate embodiments of the present disclosure and impart further understanding thereof. In connection with the description, they serve to elucidate concepts and principles of the disclosure. Other embodiments and many of the advantages mentioned are apparent with regard to the drawings. The elements of the drawings are not necessarily represented to scale with respect to one another. Elements, features and components that are identical, have the same function, and the same effect are each given the same reference numerals in the figures of the drawings, unless otherwise stated. In the figures:

FIG. 1 shows a schematic representation of an illustrative method incorporating teachings of the present disclosure;

FIGS. 2 and 3 show schematic representations of illustrative coated membranes incorporating teachings of the present disclosure;

FIG. 4 shows a schematic representation of an illustrative electrolysis cell in which the coated membrane incorporating teachings of the present disclosure is employed;

FIG. 5 shows a schematic representation of an illustrative device incorporating teachings of the present disclosure with which a membrane can be coated;

FIG. 6 shows a pulse pattern of a DC voltage having a superimposed pulse voltage incorporating teachings of the present disclosure;

FIG. 7 shows a pulse pattern of a reversal in polarity of a grid or perforated plate and a substrate holder in rapid succession in an example incorporating teachings of the present disclosure;

FIG. 8 shows by way of example possible cycle times of a deposition cycle in an example incorporating teachings of the present disclosure;

FIG. 9 shows a schematic representation of proton transport through a proton-exchange membrane having a structured deposited catalyst layer in an example incorporating teachings of the present disclosure; and

FIG. 10 shows proton transport through a thick particulate polymer layer in a comparative example of the prior art.

### DETAILED DESCRIPTION

Some embodiments of the present disclosure include methods for coating a membrane with a catalyst. For example, some embodiments include a method comprising:
a) providing a membrane in a reactor chamber;
b) coating the membrane on at least a first surface with at least one metal and/or at least one metal compound by atomic layer deposition, wherein the at least one metal and/or at least one metal compound is fed into the reactor chamber and coated onto the at least one surface of the membrane by atomic layer deposition;
c) purging the reactor chamber in such a way that metal remaining in the reactor chamber and not deposited on the at least one surface of the membrane and/or metal compound remaining in the reactor chamber and not deposited on the at least one surface of the membrane is removed from the reactor chamber;
d) generating a plasma by means of a plasma source within the reactor chamber and contacting the plasma with the at least one metal deposited on the at least one surface of the membrane and/or at least one metal compound deposited on the at least one surface of the membrane, wherein the plasma reacts with the at least one metal and/or at least one metal compound; and
e) purging the reactor chamber in such a way that volatile compounds generated during the reaction in step d) are removed.

In some embodiments, a coated membrane is produced by one or more of the methods described herein. In some embodiments, there is an electrolysis cell comprising the coated membrane.

In some embodiments, a device for coating a membrane comprises:
a reactor comprising a reactor chamber;
a substrate holder in the reactor chamber that is designed to hold a membrane;
a plasma source that is arranged inside the reactor chamber and is designed to generate from a reaction gas a plasma at least partially inside the reactor chamber;
a first supply device for at least one metal and/or at least one metal compound that is designed to supply at least one metal and/or at least one metal compound to the reactor chamber;
a second supply device for the reaction gas, which is designed to supply the reaction gas to the reactor chamber in such a way that a plasma can be generated from the reaction gas with the plasma source, especially with the aid of a generator or plasma generator; and
at least one third supply device for a purge gas, which is designed to supply at least one purge gas to the reactor chamber, it being possible to combine the at least one third supply device at least in part with the first and/or second supply device.

Unless defined differently, technical and scientific expressions used herein have the same meaning as commonly understood by a person skilled in the art in the field of the disclosure. A membrane is a biaxially stretched area of at least one material that has the ability to separate and has a selective permeability for different substances, for example gases, liquids and/or ions. The thickness of the membrane is not subject to any particular limitation here and can for example be a thickness as employed in electrolysis cells, for example of from 1.0 to 10 000.0 μm.

A membrane here has pores that determine the selective permeability, for example due to the presence of functional groups in the material of the membrane, which can give rise for example to selective permeability for cations or anions. The material of the membrane is not subject to any particular limitation, but may comprise at least one polymer. In some embodiments, the membrane comprises a polymer-based membrane that can be used in electrolysis cells, especially a cation- or anion-selective membrane, for example a proton-selective membrane, especially a polymer electrolyte membrane (PEM). In some embodiments, the membrane is a polymer exchange membrane. In some embodiments, the membrane comprises Nafion or Aquivion.

In a hydrogen-producing electrolyzer as an application of the produced membrane, the polymer exchange membrane may include a solid electrolyte. The solid electrolyte consists of a hydrophobic fluorocarbon framework similar to Teflon (PTFE) and CF₂ side chains bearing sulfonic acid groups at their chain ends. These sulfonic acid groups give the side chains hydrophilic character and are responsible for the actual proton transport. These cation conductors based on perfluorinated sulfonic acid are known under the Nafion or Aquivion names. In some embodiments, the proton-exchange membrane comprises a Nafion membrane.

Plasma is a mixture of particles at the atomic/molecular level, the constituents of which are in some cases charged components—ions and electrons—with radicals also present. In this regard, the present method can also be understood as a PEALD (plasma-enhanced atomic layer deposition) process and/or as a REALD (radical-enhanced atomic layer deposition) process, but where the formation of radicals is preferably largely avoided, especially when coating polymer-based membranes. According to particular embodiments, it is thus a PEALD method and not a REALD method that takes place in steps b) to e) of the method according to the invention.

In the application, figures are given in % by weight, unless otherwise stated or otherwise apparent from the context.

Standard pressure is 101 325 Pa=1.01325 bar.

Some embodiments include a method for coating a membrane with a catalyst, comprising:
a) providing a membrane in a reactor chamber;
b) coating the membrane on at least a first surface with at least one metal and/or at least one metal compound by atomic layer deposition, wherein the at least one metal and/or at least one metal compound is fed into the reactor chamber and coated onto the at least one surface of the membrane by atomic layer deposition;
c) purging the reactor chamber in such a way that metal remaining in the reactor chamber and not deposited on the at least one surface of the membrane and/or metal compound remaining in the reactor chamber and not deposited on the at least one surface of the membrane is removed from the reactor chamber;
d) generating a plasma by means of a plasma source within the reactor chamber and contacting the plasma with the at least one metal deposited on the at least one surface of the membrane and/or at least one metal compound deposited on the at least one surface of the membrane, wherein the plasma reacts with the at least one metal and/or at least one metal compound; and
e) purging the reactor chamber in such a way that volatile compounds generated during the reaction in step d) are removed.

In some embodiments, steps a) to e) are carried out in this order, i.e. a), b), c), d), e). Step a) is not subject to any particular limitation. The membrane may be provided in a suitable manner in the reactor chamber. For example, it may be attached, or have been attached, to a substrate holder in the reactor chamber.

In some embodiments, a reduction in pressure is applied in the reactor chamber after step a) in order to remove gases from the reactor chamber. The reduction in pressure here is not subject to any particular limitation and may for example be in the range from 10⁻⁶ to 10 mbar, for example 10⁻⁵ to 10⁻² mbar, for example approx. 10⁻³ mbar. Such a reduction in pressure may according to the invention also be applied after step b) and/or c) and/or d) and optionally after step e), in order to remove residual metal and/or residual metal compound that has not been deposited, the purge gas, and/or residual plasma or residual gas from plasma formation and also reaction products from the reaction with the plasma. In some embodiments, a reduction in pressure is also applied at least after step c), which may be formed like the reduction in pressure after step a). The reduction in pressure may be applied for example by means of a suitable vacuum pump that can be connected to the reactor chamber, for example via a valve.

Step b) of coating the membrane on at least a first surface with at least one metal and/or at least one metal compound by atomic layer deposition, wherein the at least one metal and/or at least one metal compound is fed into the reactor chamber and coated onto the at least one surface of the membrane by atomic layer deposition is not subject to any particular limitation. This can be accomplished by introducing the at least one metal and/or at least one metal compound in an appropriate manner and then contacting with the at least one first surface of the membrane and coating thereby. The atomic layer deposition (ALD) is not subject to any particular limitation and can be performed in a customary manner.

In some embodiments, more than one metal and/or one metal compound may be introduced, for example in order to subsequently produce mixed catalysts, although this can also be accomplished in separate steps, between which the reactor chamber is purged with a purge gas that is not subject to any particular limitation and is preferably an inert gas such as nitrogen and/or argon. In some embodiments, at least one metal compound, e.g. a metal compound that can constitute a precursor for the metal, undergoes coating.

In some embodiments, just as in the coated membrane, the metal and/or metal of the metal compound is not subject to any particular limitation. The metal may be one that after the plasma treatment in step d) forms a catalytically active species, for an electrolysis in particular. In some embodiments, the at least one metal or at least one metal compound comprises a metal selected from the group consisting of Ru, Rh, Pd, Ag, Os, Ir, Pt, Au, especially Ru, Rh, Pd, Os, Ir, Pt, e.g. Ir and/or Pt.

In some embodiments, these metals are able to form catalysts on the surface of the membrane. In some embodiments, the catalyst selected includes a metal oxide from the platinum group. Of the metal oxides from the platinum group, IrO₂ and RuO₂ exhibit the lowest overvoltage when going from a low oxidation state to a higher one, and thus the highest activity for an oxygen evolution reaction (OER). Although the adsorption of the oxygen-containing intermediates is sufficient for rapid charge passage, these intermediates do not adsorb so strongly, with the result that the oxygen is released after further reactions. RuO₂ corrodes during the evolution of oxygen in an acidic environment, with the formation of RuO₄ or H₂RuO₅. Iridium dioxide is considerably more stable in an acidic environment, but still exhibits sufficient activity for oxygen evolution. In some embodiments, the method according to the invention is for this reason used to apply a coating of iridium dioxide to a first surface of the membrane, especially of a proton-exchange membrane, which in an electrolysis cell in particular faces the anode side in a PEM electrolyzer. It is thus possible, by means of a physicochemical synthesis process, for example plasma-enhanced atomic layer deposition (PEALD), for a catalytically active metal oxide layer to be produced on the surface of a membrane, especially a polymer exchange membrane.

In some embodiments, step b) takes place at a temperature of less than 300° C., less than 250° C., less than 200° C., less than 150° C., and/or less than 100° C. This avoids damaging the membrane, especially when using a polymer-based membrane.

In some embodiments, the coating includes suitable metal compounds that can be coated at these temperatures, i.e. to coat with suitable precursors that are in the gaseous state at these temperatures or can at least be readily atomized at such a temperature or vaporized at a slightly higher temperature, for example up to 500° C., and can then after cooling be deposited at a correspondingly low temperature when introduced into the reactor chamber.

Examples of suitable metal compounds for the metals Ir and Pt are the following precursors:
Iridium(III) acetylacetonate

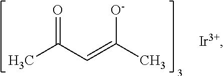

1,5-Cyclooctadiene (acetylacetonato) iridium (I)

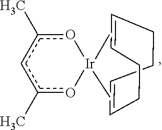

1,5-Cyclooctadiene (hexafluoroacetylacetonato) iridium (I)

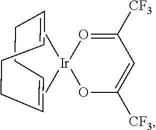

(1-Ethylcyclopentadienyl) (1,3-cyclohexadiene) iridium (I)

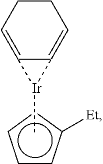

(Methylcyclopentadienyl) (1,5-cyclooctadiene) iridium (I)

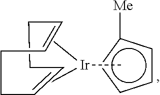

Tris (norbornadiene) (acetylacetonato) iridium(III),
Trimethyl (methylcyclopentadienyl)platinum (IV) (MeCpPtMe₃)

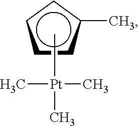

Platinum(II) acetylacetonate

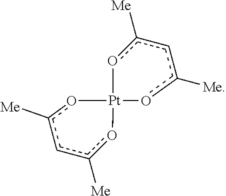

In some embodiments, when the membrane is a Nafion membrane, the precursor for platinum may be MeCpPtMe₃, and a precursor for iridium may be iridium(III) acetylacetonate, Ir(acac)₃, because Nafion has a melting point of 200° C. and at 100° C. the ionic conductivity can be lost.

In some embodiments, in step b) of coating, the at least one metal and/or at least one metal compound and/or a precursor of the at least one metal is conveyed into the reactor chamber by means of an inert carrier gas. The carrier gas is not subject to any particular limitation here but may be inert, for example N₂ and/or a noble gas such as He, Ne, Ar, Kr and/or mixtures thereof.

Likewise, step c) of purging the reactor chamber is such that metal remaining in the reactor chamber and not deposited on the at least one surface of the membrane and/or metal compound remaining in the reactor chamber and not deposited on the at least one surface of the membrane is removed from the reactor chamber, is not subject to any particular limitation, and can be effected for example with a suitable purge gas. The purge gas is not subject to any particular limitation here, but may be inert, for example N₂ and/or a noble gas such as He, Ne, Ar, Kr and/or mixtures thereof. For example, the purge gas may also be supplied from the same source as the carrier gas, i.e. it may correspond to the carrier gas.

The generation of a plasma by means of a plasma source in step d) is likewise not subject to any particular limitation and can be effected in a suitable manner. For this, a suitable generator or plasma generator may be provided in and/or outside the reactor chamber, with which the plasma can be ignited by supplying power in the form of voltage and current, although another form of plasma generation or provision of a plasma source, i.e. a source for a plasma, is not excluded.

In some embodiments, the plasma in step d) is generated using a hollow-cathode plasma source. A hollow cathode, on account of its shape, is able to trap oxygen ions and electrons in its cavities and thus ensure a higher plasma density (electron density). Furthermore, although the voltage usually falls after the plasma has been ignited, a further increase in current does not produce a greater increase in voltage. With capacitively- or inductively-coupled plasma sources, on the other hand, the voltage increases continuously with the current. This high voltage potential—almost higher than the applied voltage—accelerates the ions, which receive such a large excess of energy that the substrate surface is damaged. In the case of the hollow cathode, the plasma potential remains low, which means that the ions receive less energy and do not damage the substrate surface, i.e. the membrane.

Likewise, contacting or combining of the plasma with the at least one metal deposited on the at least one surface of the membrane and/or at least one metal compound deposited on the at least one surface of the membrane, wherein the plasma reacts with the at least one metal and/or at least one metal compound, is not subject to any particular limitation. In this case, damage to the membrane may be prevented by a suitable arrangement of the plasma source and substrate holder and membrane, where the distance therebetween may be dependent for example on the arrangement of the membrane, the geometry of the plasma source, the ignition voltage, the duration of plasma generation, etc., as appropriate. In the method, the reaction takes place at least between the coating of the membrane and the plasma, resulting in the formation from the deposited metal and/or metal compound of a catalytically active metal species, for example an oxide when using an oxygen plasma.

In some embodiments, the catalyst can be formed in a selective manner on the surface of the membrane, particularly since it is also difficult for the plasma to penetrate into the pores of the membrane. In this way, not only can clogging of the pores or any other modification that interferes with transport through the pores of the membrane be readily prevented, but the catalyst is provided at the place where it is needed. In existing methods with inks, clogging of pores can occur, with the catalyst also able to some degree to penetrate into the pores, which can lead to losses of efficiency compared to the present method, for example in an electrolysis.

The gas for plasma generation is not subject to any particular limitation and can be selected according to the catalyst to be generated but, according to particular embodiments, includes at least oxygen. In some embodiments, the plasma is in step d) generated with a gas comprising oxygen, the reaction giving rise to an oxygen compound of the at least one metal and/or of the at least one metal compound. The plasma may be generated with oxygen as plasma. With oxygen, effective metal oxides can be produced as a catalyst. Moreover, the oxygen plasma is easy to control.

In some embodiments, a grid or a perforated plate, e.g. made of metal, is in step d) arranged between the plasma source and the coated membrane. Through the grid or perforated plate, which acts as a mask here, it is possible to achieve structuring of the reaction on the membrane, for example a Nafion membrane. The grid or perforated plate is here positioned horizontally between the substrate holder and the plasma source, e.g. largely parallel or parallel to the membrane surface. In some embodiments, it is possible to adjust the height of the grid or perforated plate in the direction of the membrane, so as to be able to vary the distance between the grid or perforated plate.

The grid is not subject to any particular limitation here. It may have any suitable geometry having holes, which is not subject to any particular limitation. In some embodiments, the grid covers at least the surface of the membrane, but with the grid and membrane spaced a suitable distance apart, as described. Said distance may be varied, for example according to the structuring to be achieved, the strength of the plasma, etc. The holes in the grid may here be round, angular, square, etc. The hole size of the grid, and also the bar width between holes and the thickness of the grid, are not subject to any particular limitation. The hole size of the grid may for example be up to 1 mm, for example 10 μm to 1 mm, and/or the bar width between holes may be between 10 and 100 μm, for example 60 μm.

In some embodiments, the size of the holes may be adjusted, for example in respect of a desired catalyst area and/or also in respect of subsequent contacting, for example when using the coated membrane in an electrolysis cell. For example, with a membrane area of 56.5 cm², an active surface area of 50 cm² having a bar width between holes of 60 μm and a hole size of 1 mm is obtained.

Likewise, the perforated plate is not subject to any particular limitation and can be designed in the same way as the grid, although corresponding different geometries can arise in the perforated plate.

In some embodiments, a DC voltage generator is/has been connected to a substrate holder on which the membrane is fixed, and to the grid or perforated plate, the grid or perforated plate being connected to a negative pole of the DC voltage generator. The DC voltage generator is not subject to any particular limitation here. With the negative grid or negative perforated plate, ions of the plasma can be prevented from reaching the surface of the coated membrane in the places corresponding to the bars of the grid or away from the holes in the perforated plate, which means they do not react there.

In some embodiments, during step d) a superimposed pulsed voltage is applied to the DC voltage generator over a basic voltage in such a way that a positive and a negative voltage is alternately applied to the grid or perforated plate. In some embodiments, the superimposed voltage has a pulse frequency of 0.5 to 100 kHz, e.g. 1 to 25 kHz.

The hollow cathode effect (low plasma potential, high plasma density, as described above) and the masking grid or perforated plate, which with the substrate holder is connected to a pulsable DC voltage generator and medium-frequency generator, can result in deposition of a structured crystalline catalyst layer, for example an iridium dioxide layer when using Ir as the metal, on the surface of the membrane, for example a Nafion surface, by controlling the movement of the ions in the plasma, for example the movement of oxygen atoms and oxygen ions, so that structures are formed here that can later be adapted to the use, for example in respect of electrode contacts when used in an electrolysis cell.

A DC voltage generator may thus be connected to the grid or perforated plate and to the substrate holder via power supply leads. In some embodiments, the DC voltage generator generates at short intervals a pulsed voltage superimposed on the basic voltage having a preferred frequency of 1 to 25 kHz within the cycle time, of for example 5 s, of a plasma generator (for example comprising a hollow cathode), in order to permit a pulsed reversal in polarity of the masking grid or of the perforated plate and substrate holder. The grid or perforated plate is according to particular embodiments connected to the negative pole and the substrate holder to the positive pole of the voltage generator. The negatively charged ions of the plasma, for example oxygen ions, are attracted by the positive substrate holder and flow through the openings in the grid or perforated plate to the membrane surface, for example a Nafion surface studded with metal or metal compound or metal precursors, for example Ir precursors. Ions and atoms of the plasma, for example oxygen ions and oxygen atoms, that strike the bars of the grid or away from the holes of the perforated plate, are at this point repelled by the negatively charged grid or negatively charged perforated plate, with the result that said ions and atoms do not react with the coating of the membrane or the membrane surface. The basic voltage between the grid or perforated plate and the substrate holder may be superimposed by a pulsed voltage in order to increase the attraction effects at the substrate holder and repulsion effects at the grid bars or corresponding places of the perforated plate.

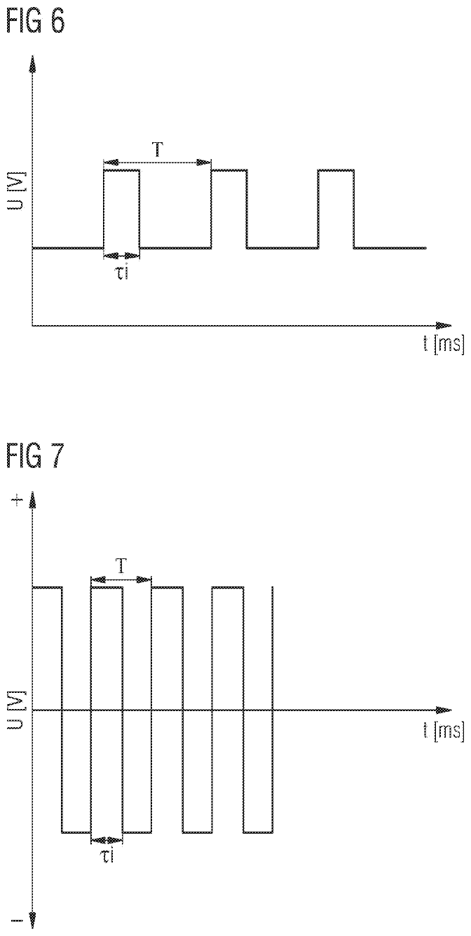

By briefly reversing the polarity of the pulse, the grid or perforated plate becomes positive and the concentration of ions and atoms on the grid or perforated plate is increased for a short time. If the reversal in polarity of the grid or perforated plate and the substrate holder is abolished, the original state is restored. The atoms and ions flow through the holes in the grid or in the perforated plate to the positively charged substrate holder and onto the coated surface of the membrane. At the negatively charged grid bars or corresponding places of the perforated plate, the ions and atoms, for example oxygen ions and oxygen atoms, are repelled back into the plasma cloud and are available for further collisions. If the reversal in polarity occurs in very short time intervals of for example 10 microseconds to 5 milliseconds, for example 40 microseconds to one millisecond, a directed beam of ions and atoms that is focused at the hole in the grid or in the perforated plate can be formed on the metal and/or metal compound or membrane surface coated with precursor molecules. For cycle times of for example 40 microseconds to one millisecond, medium-frequency generators (corresponding to 1 to 25 kHz) may for example be connected to the grid or perforated plate and to the substrate holder. With the superimposed pulse voltage or the reversal in polarity at shorter time intervals, especially of less than one millisecond, the mobility of the atoms and ions in the plasma is increased. On impact, the high-energy atoms and ions of the plasma transfer their momentum to the adsorbed precursor molecules coating the membrane, temporarily increasing their mobility. This input of energy results in heating of the substrate surface. Said effects can result in the formation of dense fibrous structures having a smooth surface. FIG. 6 and FIG. 7 show a schematic representation of possible pulse patterns for a basic voltage with a superimposed pulse voltage (FIG. 6) and for a reversal in the polarity of the basic voltage (FIG. 7). FIG. 6 shows an example of a pulse pattern of a DC voltage having a superimposed pulse voltage, where T: period duration; 1/T: frequency f; τi: pulse duration; operating cycle: τi/(T−τi)*100%; t: time; U: voltage. FIG. 7 shows an illustrative pulse pattern for a reversal in polarity of the masking grid or perforated plate and substrate holder in rapid succession from 1 to 25 kHz (medium-frequency voltage).

Step e) of purging the reactor chamber in such a way that volatile compounds generated during the reaction in step d) are removed is likewise not subject to any particular limitation. The purge gas used may be the same purge gas as in step c), but it may also be a different gas. In some embodiments, the same purge gas is used. Step e) removes undesired reaction products, resulting for example through reaction of the membrane with the plasma, from the reaction space so that they do not subsequently remain as impurities. For example, volatile CO₂ and/or H₂O molecules are removed, for example by purging with nitrogen, although the possibility cannot be excluded that other molecules, atoms and/or ions, for example remaining from the plasma, are also removed.

After step e), the coated membrane with the reacted coating may optionally be removed from the reactor chamber and supplied to its further purpose, i.e. used in an electrolysis cell, for example.

In some embodiments, steps b) to e) are carried out multiple times in succession. This makes it possible for example to bring about complete coverage of the membrane surface. It is also possible for more complex catalyst structures to be formed on the surface, such as nanoneedles, etc. In some embodiments, no intermediate steps take place between steps b) to e).

In some embodiments, one or more of these methods is executed also on both—opposite—sides of a membrane, wherein the at least one metal and/or at least one metal compound that is deposited on a surface of the membrane may or may not differ from a second at least one metal and/or a second at least one metal compound on an opposite surface of the membrane. If the at least one metal and/or at least one metal compound are different, it is possible on the opposite sides of the membrane to produce different catalysts that, in an electrolysis cell for example, are able to catalyze different reactions on the cathode side and on the anode side.

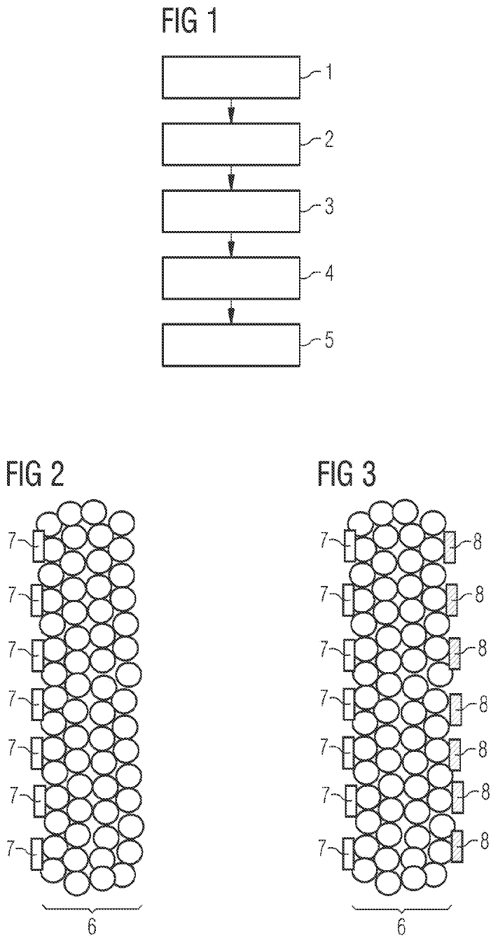

A schematic representation of a method incorporating teachings of the present disclosure is shown in FIG. 1. Step 1 of providing a membrane in a reactor chamber is followed by step 2 of coating the membrane on at least a first surface with at least one metal and/or at least one metal compound by atomic layer deposition, followed by step 3 of purging the reactor chamber in such a way that metal remaining in the reactor chamber and not deposited on the at least one surface of the membrane and/or metal compound remaining in the reactor chamber and not deposited on the at least one surface of the membrane is removed from the reactor chamber. This is followed by step 4 of generating a plasma by means of a plasma source within the reactor chamber and contacting the plasma with the at least one metal deposited on the at least one surface of the membrane and/or at least one metal compound deposited on the at least one surface of the membrane, wherein the plasma reacts with the at least one metal and/or at least one metal compound, and then by step 5 of purging the reactor chamber in such a way that volatile compounds generated during the reaction in step d) are removed.

Some embodiments of the teachings herein include a coated membrane produced by one or more of the methods described herein. The methods make it possible to produce a very thin and goal-oriented membrane that may optionally also be structured.

In some embodiments, the membrane is a polymer-based membrane, for example a Nafion membrane. The coating extends according to particular embodiments over one or both surface sides of the membrane, according to particular embodiments in each case a metal-based catalyst that is not subject to any particular limitation, for example based on Ir on one side and on Pt on the other side.

FIG. 2 shows a schematic representation of an illustrative membrane 6, for example a Nafion membrane, on which a first catalyst 7 has been produced in a structured manner by one or more of the coating methods described herein, and FIG. 3 shows an illustrative schematic representation of a membrane 6, for example a Nafion membrane, that is coated on one side with a first catalyst 7, for example an oxygen evolution reaction catalyst (OER catalyst), for example iridium dioxide, and on the other side with a second catalyst 8, for example a hydrogen evolution reaction catalyst (HER catalyst), for example platinum.

Some embodiments include an electrolysis cell comprising a coated membrane as described herein. In particular, in such an electrolysis cell the coated membrane is used to separate a cathode space comprising a cathode and an anode space comprising an anode, it being possible also for the coating of the membrane to adjoin the cathode and/or anode.

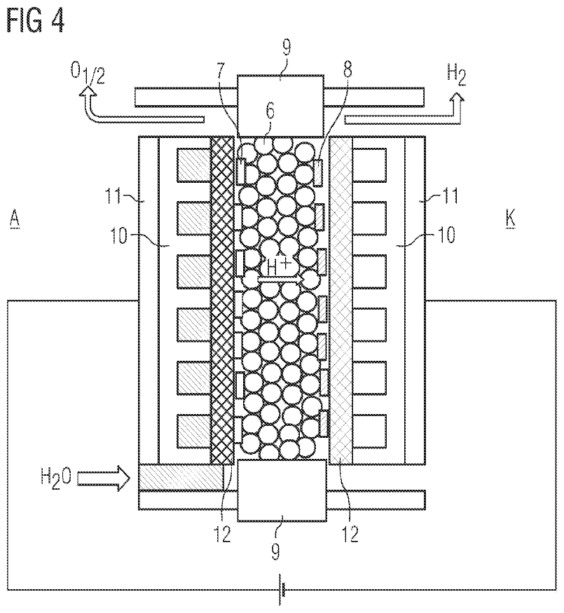

A schematic representation of an illustrative electrolysis cell is shown in FIG. 4. On the membrane 6 having a first catalyst 7, for example iridium dioxide, and a second catalyst 8, for example platinum, there are gas diffusion layers 12 adjoining the coating on each side, the membrane being sealed at the top and bottom by an replaceable further membrane 9. The electrical contact to the end plates 11 is made via bipolar plates 10, the side with iridium dioxide forming the anode A here and the side with platinum the cathode K, which are appropriately connected to a current source. The bipolar plates 10 and end plates 11 thus form current collectors, via which the current is supplied. If water is now fed into this illustrative PEM cell, oxygen is produced on the anode side and hydrogen on the cathode side. The membrane 6 is thus here fixed in an electrolysis cell, by way of example, or else in a polymer electrolysis stack between the current collectors or else gas diffusion layers 12 in the form of, for example, a proton-permeable polymer membrane, wherein the membrane 6, with its structured coated surface, may closely adjoin the current collectors and may be easily replaceable within the stack via for example a cassette lock.

In this example of an electrolysis cell, the catalyst, for example iridium dioxide, is deposited directly onto the membrane surface, for example Nafion surface, in a structured manner by means of a physicochemical process, which means there is no need to produce a catalyst ink, which usually consists of the catalyst particles, 2-propanol, distilled water and a 15 to 20% Nafion ionomer solution, and to apply the ink to the membrane either via a spray process or indirectly via a decal process with the aid of a transfer film. It is accordingly possible for the costly catalyst materials, for example iridium dioxide as an OER catalyst, but also for example the costly and uncommon HER catalysts, for example platinum, to be deposited in tiny amounts in this way using the method according to the invention. FIG. 4 accordingly shows a schematic representation of a proton-exchange membrane in an electrolysis cell or electrolysis cell unit of an electrolysis cell stack with direct OER and HER catalyst coating.

Some embodiments include the use of a coated membrane as described herein in an electrolysis cell. Some examples include use in PEM electrolysis, in which the membrane is a polymer electrolyte membrane (PEM), where an OER catalyst, for example iridium dioxide, is provided on one side of the membrane and an HER catalyst, for example platinum, optionally provided on a second side of the membrane.

Some embodiments include a device for coating a membrane, comprising:
a reactor comprising a reactor chamber;
a substrate holder in the reactor chamber that is designed to hold a membrane;
a plasma source that is arranged inside the reactor chamber and is designed to generate a plasma from a reaction gas, at least partially inside the reactor chamber;
a first supply device for at least one metal and/or at least one metal compound that is designed to supply at least one metal and/or at least one metal compound to the reactor chamber;
a second supply device for the reaction gas, which is designed to supply the reaction gas to the reactor chamber in such a way that a plasma can be generated from the reaction gas with the plasma source; and
at least one third supply device for a purge gas, which is designed to supply at least one purge gas to the reactor chamber, it being possible to combine the at least one third supply device at least in part with the first and/or second supply device.

The device may be used to execute one or more of the methods described herein. Individual embodiments of the method can accordingly also be transposed to the device and be used accordingly.

The reactor comprising a reactor chamber is not subject to any particular limitation. In particular, since a reduction in pressure can be applied to the reactor chamber, the reactor is designed in such a way that a reduction in pressure can be applied. For example, it is possible to attach to the reactor for this purpose a vacuum device comprising a vacuum pump and a vacuum shut-off device such as a valve, with which a reduction in pressure can be applied as required. The reduction in pressure may be formed as described above, such that a vacuum pump may preferably be provided that is able to generate a reduction in pressure in the range from 10⁻⁶ to 10 mbar, for example 10⁻⁵ to 10⁻² mbar, for example approx. 10⁻³ mbar.

The substrate holder in the reactor chamber is likewise not subject to any particular limitation. In particular, it is designed to hold a polymer-based membrane, i.e. it has an appropriate base area and rigidity, or it has appropriate holders for clamping in the membrane. The substrate holder may be electrically grounded.

In addition, the plasma source that is used to give rise to the plasma and also a corresponding plasma generator with which the supply of power in the form of voltage and current for igniting the plasma is achieved, are not subject to any particular limitation. In some embodiments, the plasma source is a hollow-cathode plasma source, wherein according to particular embodiments a hollow cathode for igniting the plasma may then in this case be provided in the reactor. For the generation of the plasma it is possible here to connect appropriate devices such as a matching unit and a suitable signal generator, for example an RF generator.

The first supply device for at least one metal and/or at least one metal compound, which is designed to supply at least one metal and/or at least one metal compound to the reactor chamber, is likewise not subject to any particular limitation. For example, it may include a source for the at least one metal and/or the at least one source that provides the at least one metal and/or at least one metal compound. For this provision, a heating device, for example a thermostat, may additionally be provided that heats the at least one metal and/or at least one metal compound in such a way that it is supplied to the reactor chamber as a gas, vapor, etc. in such a way that atomic layer deposition can be carried out. In addition, a source for a carrier gas that carries the at least one metal and/or the at least one metal compound into the reactor may be provided. In the first supply device it is in addition possible according to particular embodiments to provide a mass flow controller in order to set the mass flow of the at least one metal and/or at least one metal compound in a selective manner for an atomic layer deposition. To stop the flow of the at least one metal and/or at least one metal compound, a corresponding first and/or second shut-off device may be provided at the source of the at least one metal and/or at least one metal compound and/or the source of the carrier gas, for example in each case a valve that is designed to pause the mass flow of the at least one metal and/or at least one metal compound and/or of the carrier gas, for example when purging or reacting with plasma; alternatively, it is also possible to provide a common shut-off device for both or else a device shutting off the reactor chamber. Optionally, the feed of the at least one metal and/or at least one metal compound may also be controlled via the rate of heating with the heating device. In addition, the second supply device for the reaction gas, which is designed to supply the reaction gas to the reactor chamber in such a way that a plasma can be generated from the reaction gas with the plasma source, is not subject to any particular limitation, provided it supplies the reaction gas to the plasma source in such a way that a plasma can be generated. It may include a suitable source for the reaction gas, for example a source for oxygen, and a mass flow controller, so as to generate in a selective manner a plasma to an extent such that it is able to reach a surface of the membrane when this is held in the substrate holder. The second supply device may additionally be provided with a third shut-off device that is designed to stop the inflow of reaction gas, for example during atomic layer deposition and during purging.

The at least one third supply device for a purge gas, which is designed to supply at least one purge gas to the reactor chamber, it being possible to combine the at least one third supply device at least in part with the first and/or second supply device, is also not subject to any particular limitation. For example, the carrier gas for the at least one metal and/or at least one metal compound may also be used as the purge gas, so that the source of the carrier gas corresponds here to the source of the purge gas, and the first supply device is partially combined with the third supply device. Accordingly, the source for the reaction gas may be combined with a source for purge gas, for example when a plasma is formed from a reaction gas and a further gas, for example the purge gas, in which case an inflow of the purge gas can simply be maintained after plasma generation has ended. In this case, the second supply device would then be partially combined with the third supply device, especially when the purge gas is a noble gas such as argon.

In some embodiments, the device may additionally include an airlock in the reactor, via which the membrane can be introduced into the reactor chamber and the coated membrane removed. In the case of a membrane coated on both sides, this can be rotated in the reactor, consequently a corresponding suitable gripping device for rotating and/or also for positioning the membrane may optionally be provided here.

In some embodiments, the device may also include a grid or a perforated plate arranged between the plasma source and the substrate holder. In some embodiments, a DC voltage generator is connected to the substrate holder on which the membrane may be fixed, and to the grid or perforated plate, the grid or perforated plate may be connected to a negative pole of the DC voltage generator. In some embodiments, the DC voltage generator is designed in such a way that a pulsed voltage can be applied over a basic voltage. This can be accomplished for example by connecting a medium-frequency generator having a pulse frequency of for example 0.5 to 100 kHz, e.g. 1 to 25 kHz.

An illustrative device incorporating teachings of the present disclosure is described by way of example in connection with example 1 below. The above embodiments, configurations, and developments can, if viable, be combined with one another as desired. Further possible configurations, developments, and implementations include also combinations of features that have been described above or are described hereinbelow with reference to the working examples but have not been mentioned explicitly. More particularly, the person skilled in the art will also add individual aspects as improvements or additions to the respective base form of the present disclosure.

The teachings are further elucidated in detail hereinbelow with reference to various examples thereof. The scope of the disclosure is not however restricted to these examples.

### EXAMPLES

### Example 1 Deposition of Iridium Dioxide

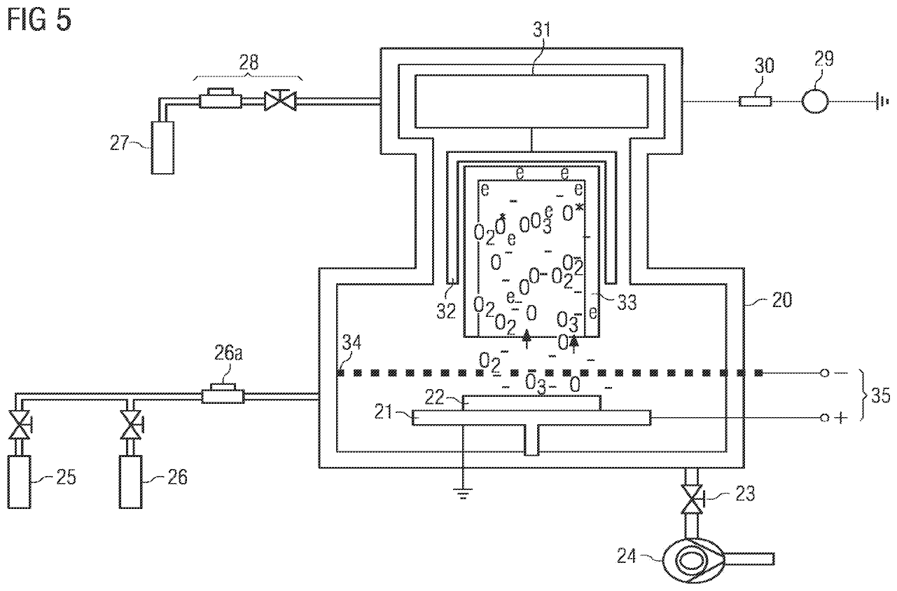

In a first example, iridium dioxide is deposited as a catalyst on a Nafion membrane as a proton-exchange membrane. The direct deposition of iridium dioxide onto the Nafion membrane can take place in an arrangement as per FIG. 5.

The membrane 22 to be coated is transported to the substrate holder 21 of the reactor 20 via an airlock (not shown). This can be grounded as shown here.

In the reactor 20, a fine vacuum of approx. 10⁻³ mbar generated via a turbopump 24 as vacuum pump, a valve 23 being provided with which to switch off the vacuum when necessary, for example when plasma generation is taking place.

The Ir precursor, for example iridium(III) acetylacetonate, Ir(acac)₃, is stored in a source for Ir precursor 26, in this case designed as an absorption vessel (bubbler) as protection against atmospheric oxygen and humidity, and is heated via a thermostat (not shown) as a function of its vapor pressure. The source for Ir precursor 26 (or for a metal precursor in general) is equipped with an infeed pipe and an exit pipe. The Ir precursor together with a carrier gas, in this case nitrogen, from the source for carrier gas 25, is conveyed via the infeed pipe to a common feed line, in this case having a mass flow controller 26a, and mixes therein with the Ir precursor vapor. The nitrogen-precursor-steam mixture exits the mass flow controller 26a via the exit pipe and is fed into the reactor pneumatically via pipes with the aid of valves. The flow of the Ir precursor into the reactor 20 is controlled and regulated by the vapor pressure of the precursor and by the controlled through-flow of the N₂ carrier gas such that a monolayer of Ir precursor is chemisorbed onto the surface of the membrane 22.

In a second step after this absorption and after shutting the valves of the sources 25 and 26, excess molecules of Ir precursor gas are removed and the reactor 20 is purged with nitrogen, for example again from the source for carrier gas 25, which serves as purge gas here. The purge gas is then shut off again.

In a third step, oxygen as an illustrative plasma gas is introduced in a selective manner from the source for plasma gas 27 via the second mass flow controller 28, in this case likewise having a valve, into a hollow-cathode plasma source 31 having a hollow cathode 32. In this hollow-cathode plasma source 31, a high voltage, for example 100 to 300 volts, is generated between anode and cathode by means of a radiofrequency plasma generator 29, impedance differences (AC resistances) that occur here being minimized and matched in a matching box 30 (or matching unit). The oxygen molecules are ionized at 12.06 eV and the oxygen atom at 13.62 eV. The discharge of the oxygen molecules takes place mainly by direct electron impact dissociation and by dissociative electron addition. Unstable excited O₂^{-*} species are formed as intermediates, which then break down into atomic oxygen and oxygen ions. Oxygen discharges are weakly negative, meaning that a proportion of the negative charge consists of ions instead of electrons. The negative ions are O⁻, O₂⁻, and even O₃⁻ and form inter alia the plasma 33. These negative oxygen ions react with the adsorbed Ir precursor on the Nafion surface of the membrane 22 with the formation of iridium dioxide and volatile CO₂ and H₂O molecules.

Nafion has a melting point of 200° C. and the ionic conductivity is lost at 100° C. Since physicochemical deposition from the gas phase via a precursor in a very thin layer (for example nanometer range) by means of an atomic-layer atom deposition process usually takes place at 180 to 200° C. in the case of iridium dioxide and at 300 to 400° C. in the case of iridium, the chemical conversion of the iridium precursor at the Nafion membrane cannot take place thermally by heating the reaction space and substrate holder 21 or the membrane 22 directly. With Nafion, the formation of the layer takes place at room temperature through the use of the plasma source. In this plasma source, the layer-forming gas receives enough energy via a discharge to convert the iridium precursor adsorbed on the Nafion surface into iridium dioxide.

In order for H⁺ ions formed at the catalyst surface during water splitting to be able to diffuse through the Nafion membrane to the cathode side in water electrolysis as an application, the entire Nafion membrane should not be covered with iridium dioxide. For this purpose, an illustrative grid 34 (alternatively a perforated plate) is provided between the hollow cathode 32 and the membrane 22 and is connected to a DC voltage generator 35. As described above, the grid 34 is connected to the negative pole of the DC voltage generator 35 and a pulsed voltage is superimposed, as a result of which iridium dioxide can be generated in a selective manner through the holes in the grid 34, but with no iridium dioxide generated in the places corresponding to the bars of the grid 34.

In a fourth step, the eliminated volatile CO₂ and H₂O molecules are removed. This is done by purging the reactor chamber and the coated Nafion membrane with nitrogen, for example from the source for carrier gas 25.

The two deposition processes described and the two purging/evacuation processes between the layer-forming steps comprise a deposition cycle that is repeated multiple times. Each individual process runs completely. The Ir precursor and the oxygen plasma are fed sequentially into the reactor chamber and undergo chemisorption onto the Nafion surface until the entire Nafion surface is covered. After that, no further adsorption processes take place. The exposure time of the individual steps is chosen such that there is sufficient time for the component that has just been introduced to react with the Nafion surface and for the excess steam and the by-products to be removed from the reactor chamber.

The adsorption time of the Ir precursor, the cleavage time into IrO₂ plus CO₂ and H₂O, and the purge times between the layer-forming processes are of the order of seconds in the example, but can vary depending on the precursor material, plasma gas, etc. With this type of process control the surface reactions are self-limiting, with the result that a reproducible iridium dioxide layer with a calculable composition is deposited. The deposited iridium dioxide grows with each subsequent cycle.

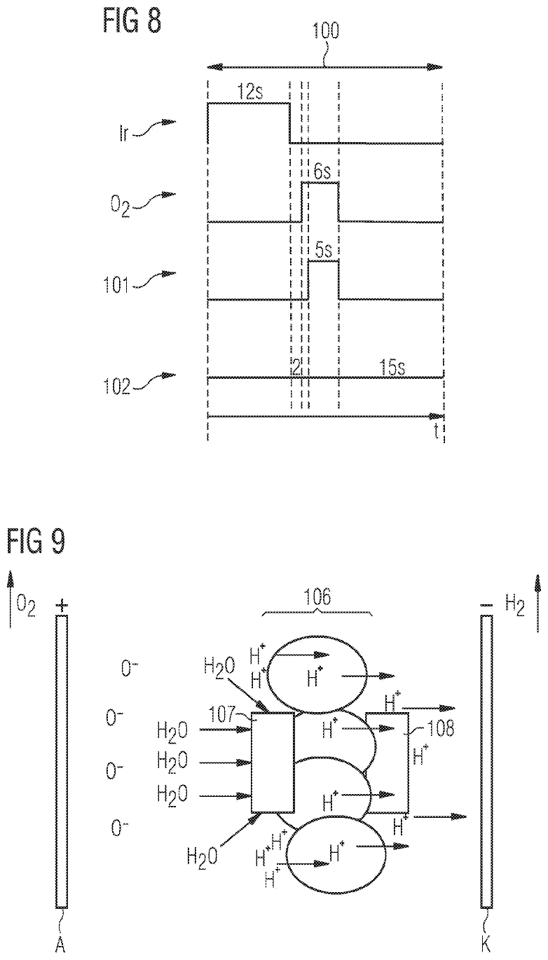

FIG. 8 shows a possible pattern of the cycle times for a deposition cycle 100, with deposition of Ir precursor for 12 seconds, a 2 s purge time 102, a 6 s plasma generation (in this case with O₂)—the last 5 s being with RF generation 101 at 100 W, followed in turn by a 15 s purge time 102, in this case with N₂ by way of example, or else with Ar as an alternative. Concomitantly with the start of plasma generation, the DC voltage generator or medium-frequency generator is also started so as to maintain a voltage between the masking grid and the substrate holder.

### Example 2 Physicochemical Deposition of Platinum (HER Catalyst)

On the cathode side in a fuel cell, a HER catalyst is usually necessary on account of the desired hydrogen generation. An example of a HER catalyst is platinum. With the method according to the invention, platinum can likewise be formed on the Nafion surface by gas-phase atomic layer deposition with the aid of a platinum precursor and can here be deposited on the second side of the coated membrane from example 1, or else of course on an uncoated membrane.

For the plasma-assisted process, MeCpPtMe₃ is used as the platinum precursor. Since Nafion has a melting point of 200° C. and ionic conductivity is lost at 100° C., MeCpPtMe₃ may be used for deposition of platinum in the form of a metallic film. The precursor MeCpPtMe₃ is heated to 31° C. Deposition in the reactor takes place at 100° C., as in example 1. The second reactant used is oxygen plasma, as in example 1, in order to cleave the methyl groups and the cyclopentadiene. Purging is likewise carried out as in example 1, i.e. the device from example 1 is used, except that the source for Ir precursor 26 is replaced by a source for the Pt precursor. The cycle times for the individual steps correspond to those of example 1, with Pt deposition taking the place of the Ir deposition. In order to obtain structuring of the platinum layer, the masking grid 34 is used during plasma generation in the deposition of platinum too. The grid is situated horizontally between the substrate holder 21 and the hollow-cathode plasma source 31. To increase the mobility of the oxygen atoms and oxygen ions on the Nafion surface, a pulsable DC voltage generator 35 and a medium-frequency generator are again connected between the masking grid and the substrate holder.

In the two examples, the catalyst is deposited from the vapor phase via a precursor and layer formation occurs through the use of a plasma. This results in a reduction in the amount of catalyst through the production of extremely thin layers in the nanometer range compared to ink-spraying technology with layer thicknesses of 10-12 μm, since commercially available iridium dioxide powders having particle sizes in the range of a few micrometers are for example used to produce a catalyst layer.

The catalysts can be applied in a structured manner with the deposition process. This means that, for example in the case of water electrolysis, the hydrogen ions formed during water splitting can easily be transported through the membrane to the cathode side in the uncoated areas of the Nafion surface.

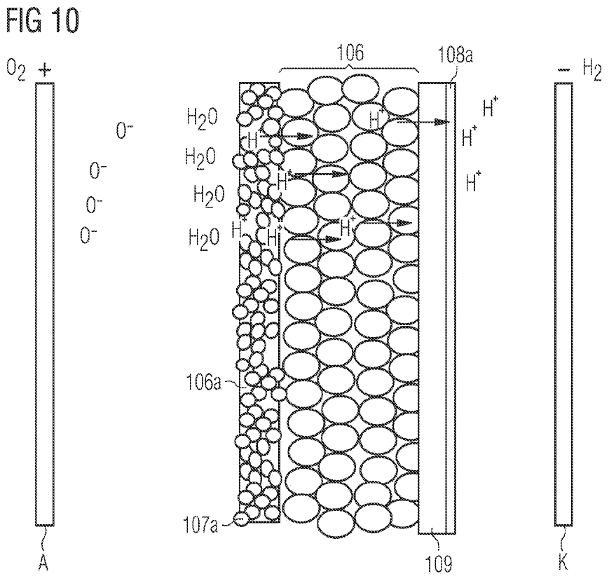

FIGS. 9 and 10 show a schematic representation of the situation described. As shown in FIG. 9, in an electrolysis cell with the membrane produced according to the invention, water introduced on the side of the anode A arrives at the structured iridium dioxide catalyst 107 of nanometer thickness on the Nafion membrane as proton-exchange membrane 106 and the protons formed during water splitting are conveyed to the structured Pt catalyst 108 on the side of the cathode K.

If the catalytically active surfaces on the proton-exchange membrane 106 have been produced by ink-spraying technology according to the prior art, as shown in FIG. 10, the hydrogen ions must first squeeze through a 10 to 12 μm thick particulate polymer layer comprising iridium dioxide particles 107a and binder 106a, for example Nafion, before the ions are able to reach the proton-conducting sulfonic acid groups of the proton-exchange membrane 106. On the side of the cathode K, a resistance likewise arises due to a carbon layer 109 as binder for the platinum layer 108a.

The methods described herein permit large savings in the amount of metal on the membrane compared to previous coating methods. For instance, taking iridium as an example, savings of about 99.3% should be achieved compared to ink-spraying technology or the decal process for an active area of equal size. In addition, the membrane, for example a PEM, is with the present method coated directly with the catalyst and not with the aid of a binder. A reduction in the amount of catalyst is achieved not through an increase in the active area, but by the nature of the deposition process.

The catalyst layer thicknesses in the atomic and nanometer range that can be produced with the method permit tunnel effects and hopping mechanisms for electron conduction. The electrons are able to jump more quickly from one localized state to a neighboring one, because the distances between layers are short. This allows the electrolysis to achieve a further increase in efficiency when the membrane produced according to the invention is used in an electrolysis cell or electrolysis stack.

If the metal and/or metal compound or precursor is deposited by atomic layer deposition, the introduction of impurities can be largely avoided or even avoided altogether, aside from unavoidable impurities. For instance, in the synthesis of iridium or iridium dioxide and platinum by atomic layer deposition, for example, it is possible to reduce or even prevent contamination by inorganic anions such as chloride, reducing agents and/or surfactants or due to precursors such as iridium chloride or platinum chloride.

The goal-oriented deposition also makes it possible to avoid larger accumulations of particles and agglomerates, since the catalysts are deposited as a coherent layer on the membrane and not as particles in the form of powder via an ink. Detachment of individual catalyst particles from the membrane is largely prevented or is not possible, since the catalyst is deposited on the membrane in the form of a continuous layer, unlike in ink-spraying technology or similar methods.

Moreover, by avoiding the use of a polymeric binder, as are present for example in inks, no signs of poisoning of the catalyst occur, for example due to the polymer. By contrast, the catalysts in ink-spraying technology, using for example iridium dioxide particles dispersed in a Nafion solution, can be poisoned by the binder.

Nafion as a binder consists essentially of a fluorocarbon framework having CF₂ side chains. The fluorine atoms are electronegatively charged on the outside through electron lone pairs. These electron lone pairs can dock onto the positive centers (electron holes) of the catalyst. As a result, the catalyst is no longer available for further chemical transformations and the formation of intermediates. The catalyst is poisoned and the catalyst activity decreases.

When catalyst metals, for example the Ir- or Pt-based active components described here by way of example, undergo gas-phase deposition on the membrane via suitable precursors, larger accumulations of particles and agglomerates can be avoided. The catalysts are consequently very well distributed both on the anode electrode and on the cathode side of an electrolysis cell, for example a PEM electrolysis cell. With good distribution, the number of active centers in the catalyst is significantly increased compared to a particle accumulation. The mass activity of catalyst, for example iridium and platinum, is increased, since iridium and platinum are used more optimally. This allows savings to be made on catalysts such as iridium and platinum.

Moreover, the physical and chemical processes of the plasma-assisted ALD method favor very thin and homogeneous coatings having the desired stoichiometry. In contrast to ink technology, the catalysts are moreover deposited as smooth layers, with the result that gas bubbles formed in electrolysis cells, for example bubbles of hydrogen or oxygen in PEM electrolysis cells, but for example other gases too in other electrolysis cells, are able to readily bead off at the smooth surfaces. In ink-spray technology, the particles are often also present as agglomerates. These agglomerates are angular, with protruding edges, and form a rough particle surface. Gas bubbles, such as bubbles of hydrogen and oxygen, adhere particularly well to these surfaces and at the prevailing voltages of 2 to 3 volts the catalysts can undergo erosion at the adhesion points. This means consumption of costly catalyst material and decreasing catalyst activity.

Atomic layer deposition moreover allows the electrochemically active materials to link together seamlessly, as a result of which there is hardly any internal resistance between the materials and charge transport can take place without hindrance. In the ALD method, surface reactions are limited by the nature of the process control itself, which means that the active materials are deposited in a layer thickness and composition that is calculable and reproducible.

The overall result is a reduction in catalyst loading (for example iridium dioxide and platinum) through the formation directly on the membrane, for example a proton-exchange membrane, of a very thin and smooth layer having a thickness in the nanometer range, bringing savings compared to the conventional procedure of about 99.3% in the case of iridium. Not only is there a reduction in the weight of the costly catalysts used, for example iridium and platinum, there is also an improvement in electrocatalytic efficiency, thus lowering the operating and capital costs for electrolysis cells. The result is an increase in the electrochemical stability of the catalyst, since very little or no erosion occurs through the smooth catalyst layers, and the service life of catalysts is correspondingly extended. This means that electrolysis cells can be scaled up to the megawatt and gigawatt range even when using costly catalysts and the process can accordingly also be implemented economically on an industrial scale. Dependence on scarce metal resources, for example iridium, is eased.

### LIST OF REFERENCE NUMERALS

1 Providing a membrane in a reactor chamber
2 Coating the membrane on at least a first surface with at least one metal and/or at least one metal compound by atomic layer deposition
3 Purging the reactor chamber in such a way that metal remaining in the reactor chamber and not deposited on the at least one surface of the membrane and/or metal compound remaining in the reactor chamber and not deposited on the at least one surface of the membrane is removed from the reactor chamber
4 Generating a plasma by means of a plasma source inside the reactor chamber and contacting the plasma with the at least one metal deposited on the at least one surface of the membrane and/or at least one metal compound deposited on the at least one surface of the membrane, wherein the plasma reacts with the at least one metal and/or at least one metal compound
5 Purging the reactor chamber in such a way that volatile compounds generated during the reaction in step d) are removed.
6 Membrane
7 First catalyst
8 Second catalyst
9 Replaceable additional membrane
10 Bipolar plate
11 End plate
12 Gas diffusion layer
20 Reactor
21 Substrate holder
22 Membrane
23 Valve
24 Vacuum pump
25 Source for carrier gas
26 Source for Ir precursor
26a Mass flow controller
27 Source for plasma gas
28 Second mass flow controller
29 Radiofrequency plasma generator
30 Matching box
31 Hollow-cathode plasma source
32 Hollow cathode
33 Plasma
34 Grid
35 DC voltage generator
100 Deposition cycle
101 RF generation
102 Purge time
106 Proton-exchange membrane
106a Binder
107 Structured iridium dioxide catalyst
107a Iridium dioxide particles
108 Structured Pt catalyst
108a Platinum layer
109 Carbon layer
A Anode
C Cathode

What is claimed is:

1. A method for coating a membrane with a catalyst, the method comprising:
a) positioning a membrane in a reactor chamber;
b) coating the membrane on a first surface with a metal by atomic layer deposition;
c) purging the reactor chamber to remove any metal remaining in the reactor chamber and not deposited on the at least one surface of the membrane;
d) generating a plasma using a plasma source within the reactor chamber and contacting the plasma with the metal deposited on the first surface of the membrane; and
e) purging the reactor chamber to remove volatile compounds generated during the reaction in step d);
wherein a grid or a perforated plate separates the plasma source and the coated membrane.

2. The method as claimed in claim 1, wherein the membrane comprises a polymer exchange membrane.

3. The method as claimed in claim 1, wherein the metal comprises a metal selected from the group consisting of Ru, Rh, Pd, Ag, Os, Ir, Pt, and Au.

4. The method as claimed in claim 1, further comprising generating the plasma with a gas comprising oxygen;
wherein the reaction generates an oxygen compound of the metal.

5. The method as claimed in claim 1, wherein coating the membrane takes place at a temperature less than 300° C.

6. The method as claimed claim 1, further comprising conveying the metal into the reactor chamber using an inert carrier gas.

7. The method as claimed in claim 1, wherein generating the plasma includes using a hollow-cathode plasma source.

8. The method as claimed in claim 1, wherein:
a DC voltage generator is connected to a substrate holder on which the membrane is fixed and to the grid; and
the grid or perforated plate is connected to a negative pole of the DC voltage generator.

9. The method as claimed in claim 8, wherein step d) further includes applying a superimposed pulsed voltage to the DC voltage generator over a basic voltage so a positive and a negative voltage are alternately applied to the grid.

10. The method as claimed in claim 9, wherein the superimposed voltage has a pulse frequency of 0.5 to 30 kHz.

11. The method as claimed in claim 1, wherein steps b) to e) are carried out multiple times in succession.

12-14. (canceled)

15. A device for coating a membrane, the device comprising:
a reactor with a reactor chamber;
a substrate holder in the reactor chamber;
a plasma source arranged inside the reactor chamber and configured to generate from a reaction gas a plasma at least partially inside the reactor chamber;
a first supply device to supply a metal to the reactor chamber;
a second supply device configured to supply the reaction gas to the reactor chamber to generate a plasma with the plasma source; and
a third supply device configured to supply a purge gas to the reactor chamber; and
a grid arranged between the plasma source and the substrate holder.
